(19) United States
(12) Patent Application Publication
(10) Pub. No.: US 2024/0397666 A1
(43) Pub. Date: Nov. 28, 2024

(54) COOLING METHOD AND APPARATUS, ESPECIALLY FOR APPLICATION IN THE FIELD OF PHOTOVOLTAICS

(71) Applicant: Freshape SA, Renens (CH)

(72) Inventors: Mathieu Rubi, Ecublens (CH); Sebastián Alagón Carrillo, Ecublens (CH); Chin Lee Ong, Ecublens (CH)

(21) Appl. No.: 18/698,244

(22) PCT Filed: Oct. 8, 2021
(86) PCT No.: PCT/IB2021/059258

§ 371 Date: Apr. 3, 2024

(51) Int. Cl. H05K 7/20; H02S 40/22; H02S 40/42; H02S 40/44

(52) U.S. Cl. CPC H05K 7/20336; H02S 40/425; H02S 40/44; H05K 7/20327; H02S 40/22

(57) ABSTRACT

A method of cooling a device generating thermal energy, which device may especially be a photovoltaic device. A thermally conductive substrate is provided, which is coupled to a portion of the device generating thermal energy to allow heat transfer therefrom to the thermally conductive substrate. A porous wick structure is further provided, which is coupled to the thermally conductive substrate. This porous wick structure is configured to be wettable by a liquid cooling medium and be partly exposed to air. The porous wick structure is wetted by means of the liquid cooling medium and subjected to the action of an airflow to cause evaporation of the liquid cooling medium at an interface between the wetted porous wick structure and air, thereby inducing cooling by evaporation. A cooling apparatus suitable for carrying out such method may also be provided.

### TECHNICAL FIELD

The present invention generally relates to a cooling method and apparatus, and the application thereof in particular in the field of photovoltaics (PV), and concentrated photovoltaics (CPV) more specifically.

### BACKGROUND OF THE INVENTION

Solar energy is widely available and sustainable, and can conveniently be converted into electricity and/or thermal energy, Today, solar energy harvesting technologies can generally be segregated into two categories:
i. solar photovoltaics (PV) that convert radiative solar energy into electrical energy; and
ii. thermal collectors that harvest heat from the sun to produce useful thermal energy.

PV cells conveniently and effectively convert solar energy into electricity. Worldwide growth of PV technology has been exponential and PV technology will soon become a more viable “green” and sustainable mainstream electricity source.

Traditional PV cells generally consist of single-junction solar cells (e.g. silicon cells) or multi-junction cells that comprise multiple material layers of multiple bandgaps responding to multiple electromagnetic wavelengths (and typically exhibiting higher conversion efficiency than single-junction cells). PV technology becomes highly attractive when sunlight concentration is deployed, as materials costs are lowered by reducing the effective area size of the PV cells. Concentrated photovoltaics (CPV) is therefore becoming an increasingly more attractive solution. This being said, while sunlight concentration increases PV cell conversion efficiency, cell temperature is also drastically increased.

Paradoxically, PV cell conversion efficiency also drops when junction temperature rises. More specifically, the open circuit voltage drops with increasing cell junction temperature, reducing electricity output as a result. In other words, efficient thermal management and cooling of PV/CPV cells must be implemented in order to maintain the cells within nominal operating conditions. The thermal aspect related to cooling of PV/CPV cell modules has fast become a bottleneck that potentially hinders the growth of this technology.

There is no best method for cooling, but rather a multitude of cooling approaches, and intensive research has been conducted in the domain of PV cooling technologies to prevent thermal runaway of the solar cells. The paper entitled “A review of solar photovoltaic systems and cooling technologies”, A G Lupu et al., IOP Conference Series: Materials Science and Engineering, Volume 444, Issue 8, 2018 (https://doi.org/10.1088/1757-899X/444/8/082016), the content of which is incorporated herein by reference, provides an overview of relevant cooling concepts and discusses the pros and cons of each cooling concept, including (i) air-cooling concepts, (ii) liquid-cooling concepts, and (iii) hybrid cooling concepts.

Air-cooling concepts can be segregated into passive or active cooling technologies. Passive air-cooling concepts essentially rely only on natural convection for heat dissipation, with an average heat transfer coefficient of the order of approximately 1 to 10 W/m²K. Active air-cooling concepts typically rely on the use of ventilators to induce forced air circulation over a heat sink to enhance heat transfer, with an average heat transfer coefficient ranging from approximately 20 to 100 W/m²K. Main advantages include simplicity and low-cost implementation and operation. Main disadvantages include lowest cooling performance compared to other solutions, such as liquid-cooling concepts, inferior cooling medium efficiency, and therefore higher PV cell junction temperatures when applied in the field of photovoltaics, which renders this cooling solution unsuitable for application to CPV especially.

Liquid-cooling concepts use a liquid medium as coolant and can likewise be segregated into passive or active cooling technologies. Water is the most common cooling medium used in practice, but other liquids than water can be used. Water-cooled PV cells exhibit higher electrical efficiency than air-cooled counterparts due to the higher cooling efficiency of water compared to that of air. Main advantages in the field of PV therefore include higher electrical conversion efficiency, the ability to harvest thermal energy, and increased heat sink compactness compared to air-cooled solutions. Main disadvantages include higher implementation costs, fouling, corrosion and erosion of the cooler, high pumping power (i.e. increased electricity consumption), and more complicated cooling circuitry.

Active liquid-cooling concepts can mainly be divided into (i) liquid immersion concepts, (ii) jet impingement concepts, and (iii) macro/microchannel heat sink concepts.

Liquid immersion involves immersing the PV cells in liquid, such as water. Such solutions are however relatively complex to implement and require sophistication to prevent any liquid leakage that could otherwise potentially cause short-circuits. Moreover, the immersion of PV cells into liquid reduces light transmission which then results in lower electricity production.

Jet impingement involves the spraying of liquid (e.g. water) over the surface to be cooled. Such solutions are however very costly to implement, both from a capital expenditure (CAPEX) perspective and an operational expenditure (OPEX) perspective. Spray cooling further requires high pumping power (and therefore increased electricity consumption), leads to massive loss of coolant, which needs to be constantly resupplied, and renders this solution unsuitable for thermal energy harvesting as coolant is dissipated. Such a solution is especially wholly inadequate for use in geographical regions which suffer from absolute water scarcity where solar insolation is at the highest.

Macro/microchannel heat sink cooling involves the use of a heat exchanger with a forced flow of cooling medium (usually water) within macrochannels or microchannels formed within the heat sink. Macrochannel heat sink concepts are widely used for large PV panels, preferably without or very low sunlight concentration. Microchannel heat sink concepts are typically deployed for CPV modules due to the higher heat transfer coefficients of such solutions. Main advantages in the PV field therefore include higher electrical conversion efficiency, and therefore applicability to CPV, and the ability to harvest thermal energy. Main disadvantages include high integration and implementation costs, fouling, corrosion and erosion of the cooler, high pumping power (i.e. increased electricity consumption), especially for CPV modules with high sunlight concentration, and complicated cooling circuitry. Average heat transfer coefficient can typically range between 1′000 and 15000 W/m²K.

Hybrid cooling concepts capitalize on the advantages of multiple combined cooling concepts to achieve the desired cooling performance. Known hybrid solutions for instance include (i) so-called heat pipe concepts, (ii) phase-change material (PCM) concepts, and (iii) thermoelectric (TE) concepts.

All of the aforementioned cooling concepts have certain limitations, disadvantages and/or drawbacks, especially for application to concentrated photovoltaics (CPV), and there therefore remains a need for an improved solution.

### SUMMARY OF THE INVENTION

A general aim of the invention is to provide a cooling method and system that obviate the limitations and drawbacks of the prior art solutions and that are in particular suitable for PV applications, including but not limited to CPV applications.

More specifically, an aim of the present invention is to provide such a solution that is compact, yet exhibits high cooling efficiency.

A further aim of the invention is to provide such a solution that can especially be applied for efficient thermal management of PV/CPV cell junction temperature.

Another aim of the invention is to provide such a solution that allows increase of the cooling power density, and therefore increase of power density when applied to CPV in particular.

Yet another aim of the invention is to provide such a solution that also allows for efficient co-generation of electricity and thermal energy.

Another aim of the invention is to enable recovery and re-use of thermal energy from the cooling process to sustain further processes relying on thermal energy as driving force.

These aims, and others, are achieved thanks to the solutions defined in the claims.

There is accordingly provided a cooling method, the features of which are recited in claim 1, namely a method of cooling a device generating thermal energy comprising the following steps:
(a) providing a thermally conductive substrate coupled to a portion of the device generating thermal energy to allow heat transfer from the device generating thermal energy to the thermally conductive substrate;
(b) providing a porous wick structure coupled to the thermally conductive substrate, which porous wick structure is configured to be wettable by a liquid cooling medium and be partly exposed to air;
(c) wetting the porous wick structure by means of the liquid cooling medium; and
(d) subjecting the wetted porous wick structure to the action of an airflow to cause evaporation of the liquid cooling medium at an interface between the wetted porous wick structure and air, thereby inducing cooling by evaporation.

Advantageous and/or preferred embodiments of this cooling method form the subject-matter of dependent claims 2 to 28.

There is further provided a cooling apparatus, the features of which are recited in independent claim 29, namely a cooling apparatus for carrying out cooling of a device generating thermal energy, comprising:
a thermally conductive substrate that can be coupled to a portion of the device generating thermal energy to allow heat transfer from the device generating thermal energy to the thermally conductive substrate;
a porous wick structure coupled to the thermally conductive substrate, which porous wick structure is configured to be wettable by a liquid cooling medium and to be exposed to air;
coolant circuitry configured to wet the porous wick structure by means of the liquid cooling medium, which coolant circuitry is coupled to the porous wick structure to supply the liquid cooling medium; and
airflow circuitry configured to subject the wetted porous wick structure to the action of an airflow to cause evaporation of the liquid cooling medium at an interface between the wetted porous wick structure and air, thereby inducing cooling by evaporation.

Advantageous and/or preferred embodiments of this cooling apparatus form the subject-matter of dependent claims 30 to 47.

Also claimed is a solar energy harvesting system comprising a solar energy harvesting device that is thermally coupled to a cooling apparatus according to the invention.

Advantageous and/or preferred embodiments of this solar energy harvesting system form the subject-matter of dependent claims 49 to 52 and 58.

Further claimed is a combined solar energy harvesting and atmospheric water generation system comprising:
at least one atmospheric water generation unit including an adsorption-desorption system configured to extract water from ambient air; and
a solar energy harvesting system according to the invention,

wherein the adsorption-desorption system comprises a heat exchanger stage which is flowed through by hot humid air exiting the porous wick structure to undergo condensation, thereby releasing latent heat to sustain desorption in the adsorption-desorption system.

Advantageous and/or preferred embodiments of this combined solar energy harvesting and atmospheric water generation system form the subject-matter of dependent claims 54 to 58.

Further advantageous embodiments of the invention are discussed below.

### BRIEF DESCRIPTION OF THE DRAWINGS

Other features and advantages of the present invention will appear more clearly from reading the following detailed description of embodiments of the invention which are presented solely by way of non-restrictive examples and illustrated by the attached drawings in which:

FIG. 1 is a schematic illustration of a cooling apparatus in accordance with one embodiment of the invention;

FIG. 2 is an explanatory illustration showing wetting of a porous wick structure of the cooling apparatus of FIG. 1;

FIG. 3 is an explanatory illustration showing the wetted porous wick structure of FIG. 2 being subjected to the action of an airflow to induce evaporative cooling at the interface between air and the wetted porous wick structure;

FIG. 4 is a schematic illustration of a cooling apparatus in accordance with another embodiment of the invention;

FIGS. 5A and 5B are two schematic illustrations of embodiments of solar energy harvesting systems, namely concentrated photovoltaic (CPV) systems, incorporating a cooling apparatus in accordance with the invention;

FIGS. 6A and 6B are schematic, exploded perspective views, taken along two different viewing angles, of a cooling apparatus in accordance with a further embodiment of the invention;

FIG. 7 is a schematic perspective view of a cooling apparatus in accordance with another embodiment of the invention;

FIG. 8 is a schematic perspective view of a cooling apparatus in accordance with an additional embodiment of the invention;

FIG. 9 is a schematic perspective view of a cooling apparatus in accordance with yet another embodiment of the invention;

FIG. 10 is a schematic diagram of an embodiment of a solar energy harvesting system, namely a photovoltaic (PV) system, provided with a cooling apparatus in accordance with the invention, which system further implements earth heat rejection and water recovery from the hot moist air exiting the cooling apparatus;

FIG. 11 is a schematic diagram of an embodiment of a combined solar energy harvesting and atmospheric water generation system, including a photovoltaic system having a photovoltaic device that is provided with a cooling apparatus in accordance with the invention, which combined system also implements earth heat rejection and water recovery from the hot moist air exiting the cooling apparatus; and

FIG. 12 is a chart showing experimental results obtained with a prototype of a cooling apparatus designed in accordance with the principle shown in FIG. 1.

### DETAILED DESCRIPTION OF EMBODIMENTS OF THE INVENTION

The present invention will be described in relation to various illustrative embodiments. It shall be understood that the scope of the invention encompasses all combinations and sub-combinations of the features of the embodiments disclosed herein.

As described herein, when two or more parts or components are described as being connected, attached, secured or coupled to one another, they can be so connected, attached, secured or coupled directly to each other or through one or more intermediary parts.

Embodiments of the invention will especially be described hereinafter in the particular context of an application thereof in the field of photovoltaics (PV), and concentrated photovoltaics (CPV) more specifically, but it will be appreciated that other applications could be contemplated, including e.g. thermal management of power electronics. In effect, the cooling methodology of the invention is applicable to any field involving use of a device generating thermal energy and requiring implementation of cooling measures.

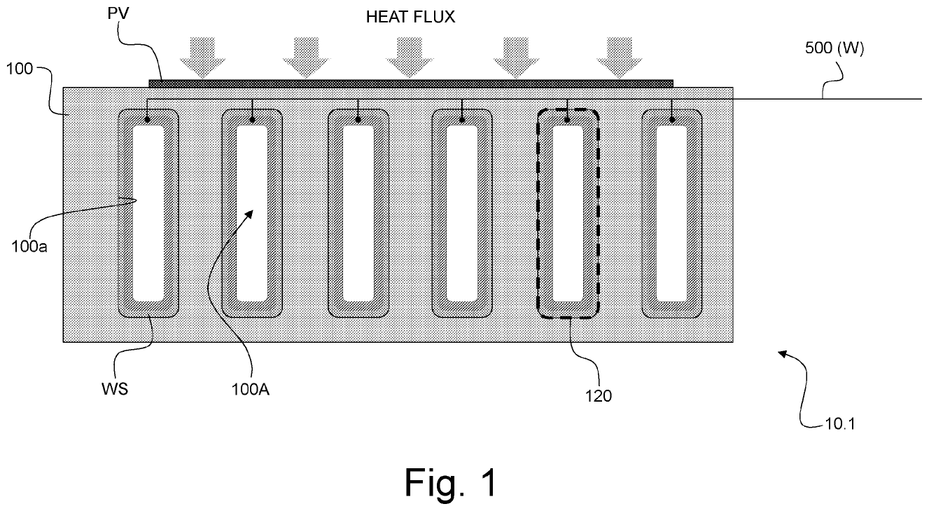

FIG. 1 is a schematic illustration of a cooling apparatus, designated by reference sign 10.1, in accordance with one embodiment of the invention. The device generating thermal energy and requiring cooling is here schematically shown as a photovoltaic device PV comprising one photovoltaic cell. Portion of the photovoltaic device PV is coupled to a thermally conductive substrate, designated generally by reference numeral 100, to allow heat transfer from the photovoltaic device PV to the substrate 100. The thermally conductive substrate 100 may be any substrate exhibiting good thermal conductivity, including e.g. a metallic substrate, such as an aluminium, copper or steel substrate, or a silicon substrate (which applies to all embodiments disclosed herein). The thermally conductive substrate 100 in effect acts as a heat sink, with specific additional means being provided to ensure efficient cooling of the photovoltaic device PV as explained hereafter.

In the example shown in FIG. 1, a plurality of cavities 100a are formed within the thermally conductive substrate 100, six such cavities 100a being depicted. In accordance with the invention, a porous wick structure WS is provided, which is coupled to the substrate 100. More specifically, the porous wick structure WS is provided, in the illustrated example, on inner walls of the cavities 100a, leaving a passage 100A to allow air to circulate therein. One will thus understand that the porous wick structure WS is in effect partly exposed to air.

The porous wick structure WS may be formed directly on the thermally conductive substrate 100. If necessary or adequate, a thermally conductive coating 120 may be provided at an interface between the thermally conductive substrate 100 and the porous wick structure WS for improved thermal conductivity. Any suitable thermally conductive coating could come into consideration, including but not limited to fine diamond coatings, copper matrix composites with diamond reinforced particles such as Cu—Zr/diamond composites, titanium coated diamond particles, and thermal adhesives comprising metallic compounds such as indium, metal oxides, and silica compounds. In all cases, good thermal conductivity between the thermally conductive substrate 100 and the porous wick structure WS should be ensured for maximum cooling efficiency, as the porous wick structure WS is meant to play an essential role in the cooling and extraction of heat. More specifically, the porous wick structure WS is designed to induce cooling by evaporation, as explained in greater detail hereafter.

According to the invention, the porous wick structure WS is specifically designed and configured to be wettable by a liquid cooling medium W, such as water. As schematically shown in FIG. 1, liquid cooling medium W is supplied to the porous wick structure WS by means of suitable coolant circuitry 500 feeding the liquid cooling medium W to relevant portions of the porous wick structure WS. By way of preference, the porous wick structure WS is wetted by capillary action, namely by supplying the liquid cooling medium W in contact with at least one portion of the porous wick structure WS to ensure optimal wetting of the whole structure.

The porous wick structure may be formed by any adequate technique. Sintering especially comes into consideration as porosity of the resulting sintered structure can reasonably be controlled to remain within desired tolerances. In that regard, and irrespective of the actual technique used to produce the porous wick structure WS, porosity thereof should ideally be comprised between approximately 20% and 80%. In accordance with a preferred embodiment of the invention, the porous wick structure advantageously exhibits pores having an average size comprised between approximately 5 μm and 50 μm.

Thickness of the porous wick structure WS will be selected in accordance with the particular cooling configuration and requirements. By way of preference, such thickness can be comprised between approximately 0.1 mm and up to 3 mm, which is normally sufficient to ensure adequate wetting of the structure and optimal cooling efficiency. Other dimensions could however be contemplated depending on the cooling power loading and geometrical constraints of the relevant cooling apparatus.

The aforementioned considerations regarding the configuration of and the relevant techniques used to produce and form the porous wick structure WS are likewise applicable to all embodiments disclosed herein.

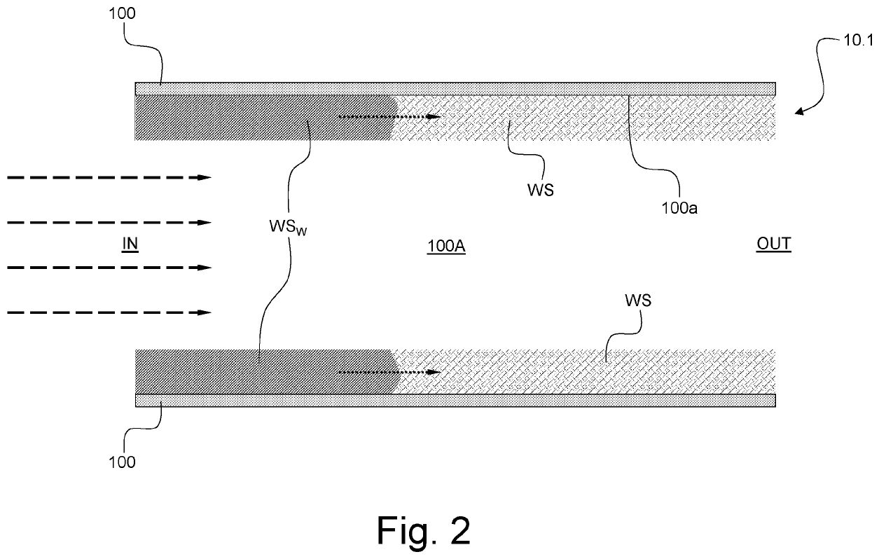

FIG. 2 is an explanatory illustration showing wetting of the porous wick structure WS of the cooling apparatus 10.1 of FIG. 1. As mentioned, the porous wick structure WS may ideally be wetted by capillary action using suitable cooling circuitry 500 (not shown in FIG. 2) to supply the appropriate amount of liquid cooling medium W to guarantee optimal wetting of the entire porous wick structure WS. In that regard, liquid cooling medium W will be supplied at one or more supply points to ensure that the porous wick structure WS can be fully wetted by capillary action and remains in a wetted state for as long as cooling is required. Supply of liquid cooling medium W may be ensured by the provision of a suitable pump or micro-pump sufficient to ensure continuous (or semi-continuous) supply of liquid cooling medium W.

FIG. 2 schematically illustrates one longitudinal cavity 100a (and porous wick structure WS provided therein) formed within the thermally conductive substrate 100 and extending from an inlet side IN to an outlet side OUT, leaving the passage 100A free to allow air circulation therein. For the sake of illustration, the porous wick structure WS is depicted in FIG. 2 in a partly wetted state, reference sign WS_{W} designating the wetted portions of the porous wick structure WS. The arrows shown in FIG. 2 schematically illustrate the direction in which wetting of the porous wick structure WS occurs by capillarity, namely from left to right in FIG. 2.

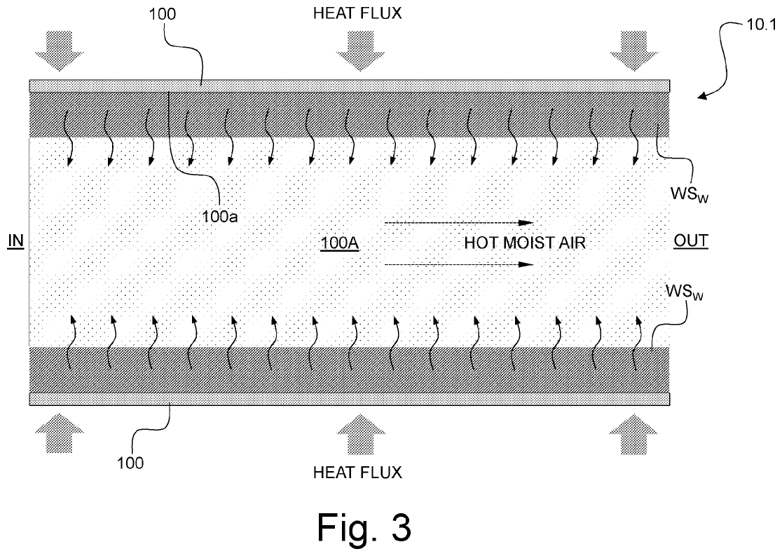

FIG. 3 is an explanatory illustration showing the now fully wetted porous wick structure WS of FIG. 2 being subjected to the action of an airflow. In the illustrated example, the airflow is understood to circulate from the inlet side IN to the outlet side OUT, as schematically indicated by the pair of arrows in FIG. 3. When in operation, thermal energy generated by the device to be cooled is transferred via the thermally conductive substrate 100 (and the optional thermally conductive coating 120) to the wetted porous wick structure WS. Under the action of the airflow flowing through each passage 100A, evaporative cooling is induced at the interface between air and the wetted porous wick structure WS, in a process that can be referred to as thin film evaporation. As a result, heat is taken away from the system, which heat is extracted as hot moist air exiting the porous wick structure WS at the outlet side OUT. The invention, and all of the embodiments discussed herein, are based on this evaporative cooling principle.

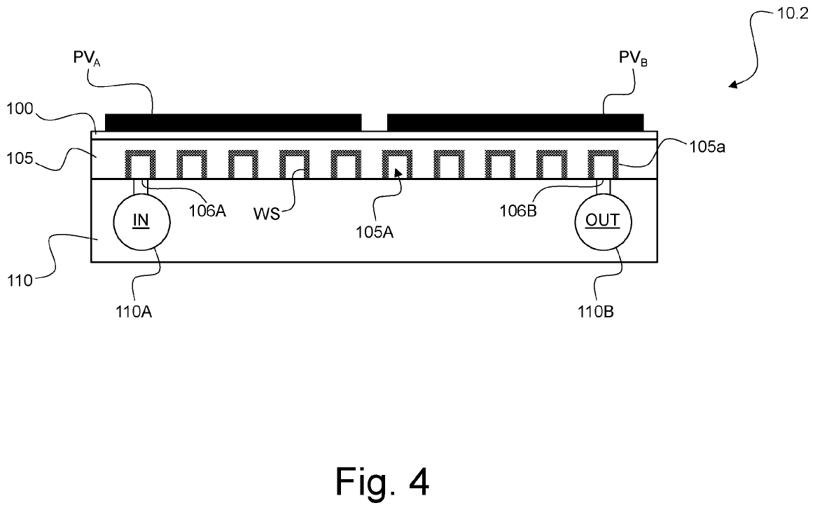

FIG. 4 is a schematic illustration of a cooling apparatus, designated by reference sign 10.2, in accordance with another embodiment of the invention. The device generating thermal energy and requiring cooling is here schematically shown for the sake of illustration as a photovoltaic device comprising two individual photovoltaic cells PV_{A}, PV_{B}. Portion of the photovoltaic device PV_{A}/PV_{B} is once again coupled to a thermally conductive substrate 100 to allow heat transfer from the photovoltaic device PV_{A}/PV_{B} to the substrate 100.

In the example shown in FIG. 4, the thermally conductive substrate 100 is thermally coupled to a further substrate component 105 that is provided with a plurality of channels 105a, ten such channels 105a being depicted. The substrate component 105 is preferably made of the same material as the thermally conductive substrate 100 (although combinations of different materials could be contemplated within the scope of the invention) and the assembly 100/105 consisting of the thermally conductive substrate 100 and associated substrate component 105, which are attached together, may be considered as one and a same substrate. One will therefore appreciate that the invention is applicable irrespective of the particular configuration of the thermally conductive substrate, be it monolithic (as shown e.g. in FIG. 1) or composed of multiple substrate components (as shown e.g. in FIG. 4).

In accordance with the invention, a porous wick structure WS is likewise provided, which is coupled to the substrate 100/105. More specifically, the porous wick structure WS is provided, in the illustrated example, on inner walls of the channels 105a, leaving a passage 105A to allow air to circulate therein. One will once again understand that the porous wick structure WS is in effect partly exposed to air and configured to be wettable by a liquid cooling medium W, such as water, in particular by capillary action.

Also depicted in FIG. 4 is a cooling manifold 110 providing adequate connection to the porous wick structure WS for the purpose of supplying the liquid cooling medium Wand wetting the porous wick structure WS, as well as ensuring airflow circulation for inducing evaporative cooling. While not specifically depicted in the schematic illustration of FIG. 4, one will understand that the connection is such that airflow is made to circulate through each passage 105A, it being understood that the channels could indifferently be individual channels or be connected together to form a channel network.

More specifically, the cooling manifold 110 includes a coolant port (not shown in FIG. 4) coupled to a suitable coolant inlet for wetting of the porous wick structure WS by means of the liquid cooling medium W, an air inlet port 110A coupled to an air inlet 106A at an inlet side IN of the porous wick structure WS, and an air outlet port 110B coupled to an air outlet 106B at an outlet side OUT of the porous wick structure WS.

In the illustration of FIG. 4, one may note that the cooling manifold 110, which is attached to the lower side of the substrate component 105, also laterally encloses the channels 105a and related passages 105A. This configuration may facilitate provision of the required porous wick structure WS on the thermally conductive substrate 100/105 as the channels 105 are in effect formed on a side of the substrate 100/105 that is readily accessible prior to attachment of the substrate 100/105 to the relevant side of the cooling manifold 110.

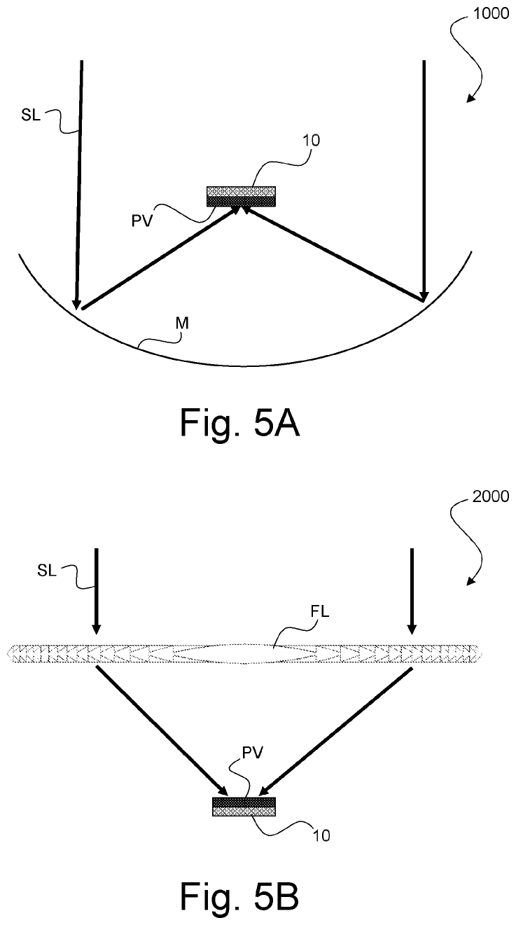

FIGS. 5A and 5B are schematic illustrations of first and second embodiments of a solar energy harvesting system 1000, respectively 2000, incorporating a cooling apparatus of the invention, designated here generically by reference numeral 10. In the illustrated examples, the solar energy harvesting systems 1000, 2000 are in effect concentrated photovoltaic (CPV) systems each comprising a photovoltaic device PV coupled to the cooling apparatus 10, which can be any cooling apparatus within the scope of the invention, including any one of cooling apparatuses 10.1 to 10.6 depicted in FIGS. 1 to 4 and 6A-B to 9.

Referring more specifically to FIG. 5A, there is shown a CPV system 1000 comprising a concave mirror M configured to concentrate sunlight SL onto the photovoltaic device PV. Referring to FIG. 5B, there is shown a CPV system 2000 comprising a converging Fresnel lens structure FL configured to likewise concentrate sunlight SL onto the photovoltaic device PV. The invention is evidently not limited to any particular solar energy harvesting configuration, and the systems schematically shown in FIGS. 5A and 5B are merely meant to illustrate possible implementations of the cooling principle of the invention.

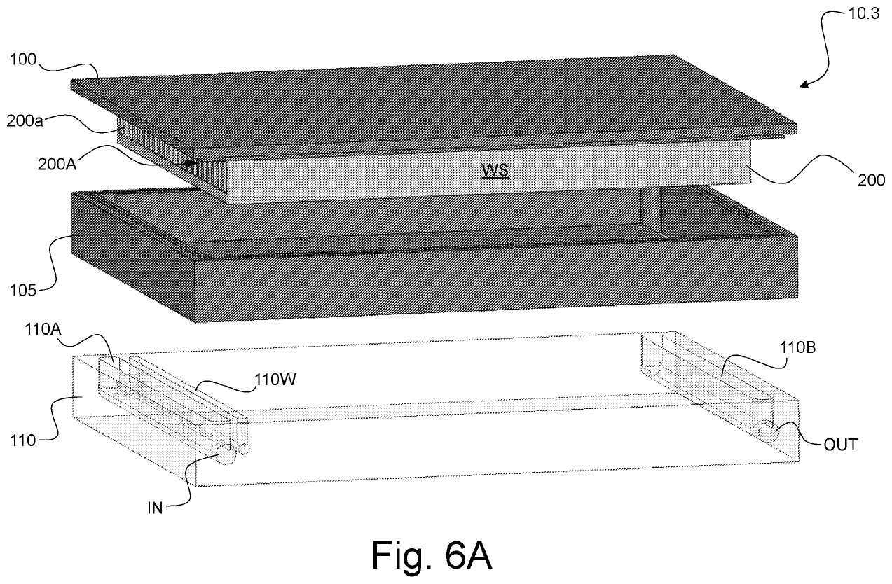

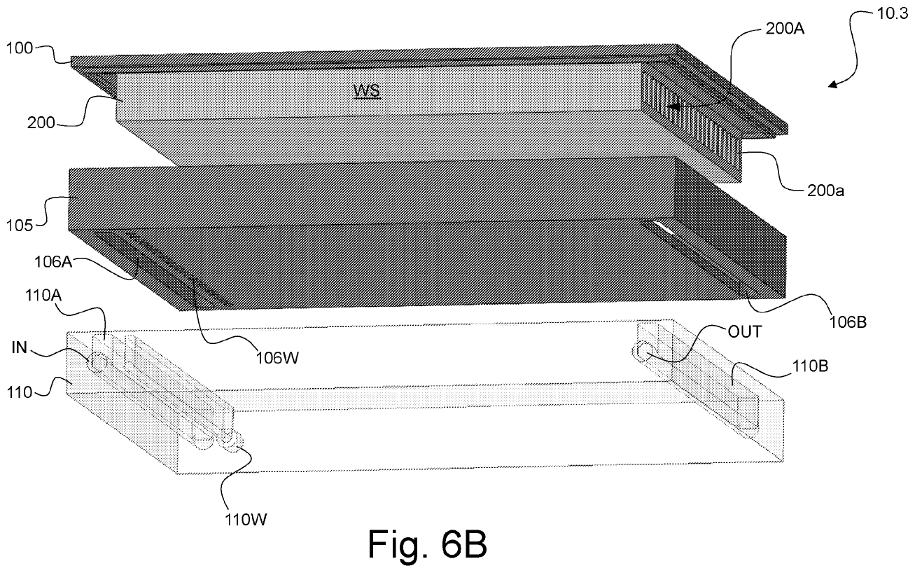

FIGS. 6A and 6B are schematic, exploded perspective views, taken along two different viewing angles, of a cooling apparatus 10.3 in accordance with a further embodiment of the invention. Visible in FIGS. 6A-B are the thermally conductive substrate 100 and associated substrate component 105, as well as the aforementioned cooling manifold 110. In the illustrated example, the porous wick structure WS is configured as a dedicated wick structure 200 that is provided on the thermally conductive substrate 100 and encased by the substrate component 105 when attached to the substrate 100. In the illustrated example, the wick structure 200 itself is configured to create a plurality of longitudinal cavities 200a extending through the wick structure 200 so as to leave a passage 200A for the airflow.

Also visible in FIGS. 6A-B are the coolant port, designated by reference sign 110W, air inlet port 110A, and air outlet port 110B of the cooling manifold 110 that are respectively coupled to the coolant inlet, designated by reference sign 106W, the air inlet 106A, and the air outlet 106B that are here provided on the underside of the substrate component 105 that encases the wick structure 200. When assembled, one will appreciate that the coolant inlet 106W (that is coupled to the coolant port 110W) communicates with the wick structure 200 to permit wetting thereof by means of the liquid cooling medium W, while the air inlet 106A and outlet 106B (that are respectively coupled to the air inlet port 110A and air outlet port 110B) establish communication with the wick structure 200 at the inlet and outlet sides IN, OUT to allow airflow to circulate through the longitudinal cavities 200a and passage 200A formed therein.

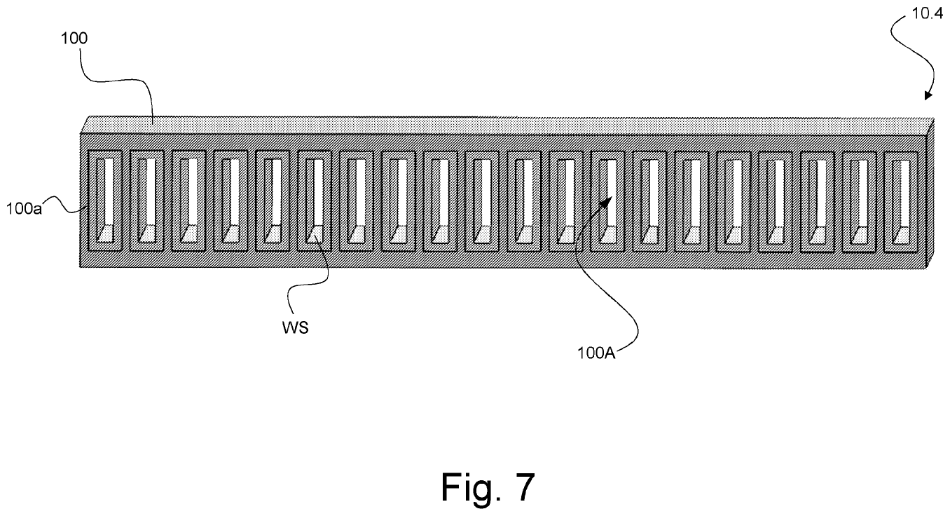

FIG. 7 is a schematic perspective view of a cooling apparatus 10.4 in accordance with another embodiment of the invention. Cooling apparatus 10.4 exhibits a configuration similar to that of cooling apparatus 10.1 of FIGS. 1-3, with a plurality of cavities 100a being formed in the thermally conductive substrate 100. The porous wick structure WS is likewise formed on inner walls of the cavities 100a to leave a passage 100A for the airflow.

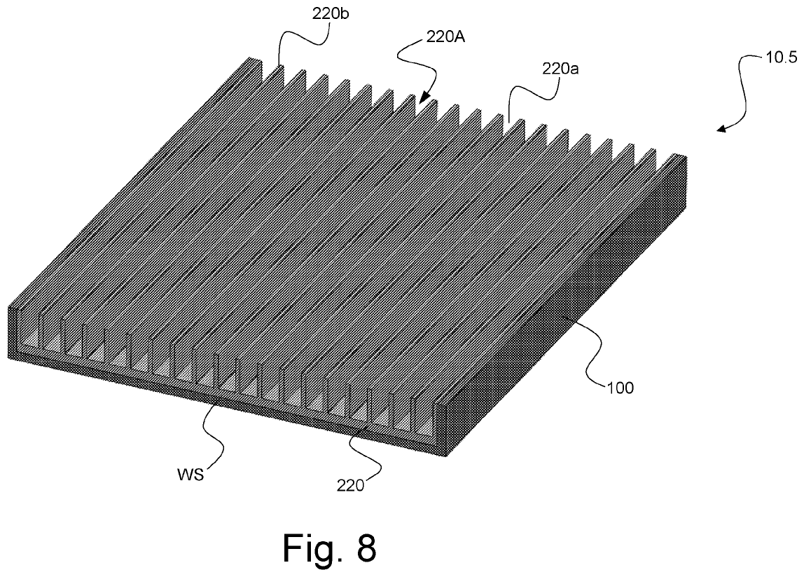

FIG. 8 is a schematic perspective view of part of a cooling apparatus 10.5 in accordance with an additional embodiment of the invention, which highlights another advantageous form of a porous wick structure WS. In this case, the porous wick structure WS is configured as a channelled fin structure 220 that is provided on the thermally conductive substrate 100 and shaped to create a plurality of longitudinal channels 220a separated by longitudinal fins 220b, likewise leaving a passage 220A for the airflow.

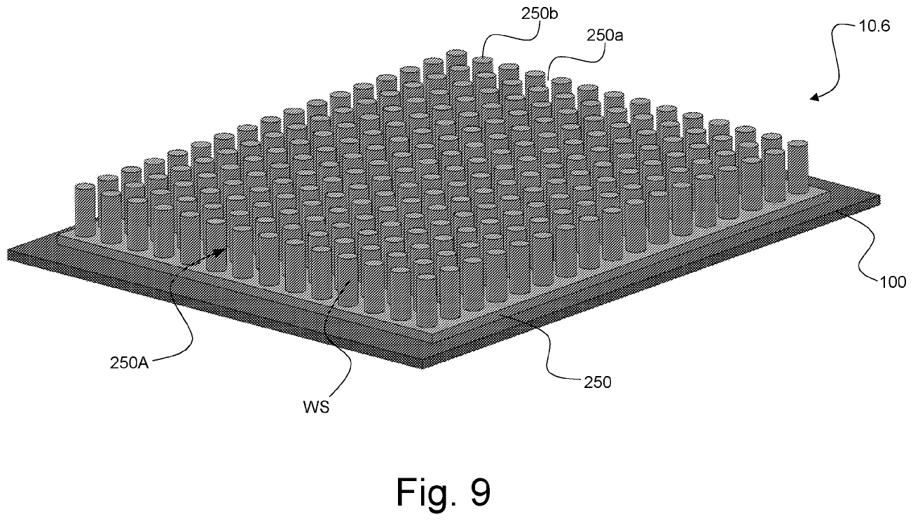

FIG. 9 is a schematic perspective view of part of a cooling apparatus 10.6 in accordance with yet another embodiment of the invention, which likewise highlights yet another advantageous form of a porous wick structure WS. In this case, the porous wick structure WS is configured as a pin-fin structure 250 that is provided on the thermally conductive substrate 100 and shaped to create a channel network 250a between and around a plurality of spaced-apart protruding pins 250b, likewise forming a passage 250A for the airflow. In the illustrated example, the protruding pins 250b are distributed to form an array of protruding pins that extend substantially perpendicularly to the path of the airflow. More specifically, the protruding pins 250b are arranged in a regular pattern of rows and columns, but other arrangements, such as staggered or zigzag arrangements, could be contemplated. In particular, the protruding pins 250b could be arranged in a staggered pattern, thereby forming a more intricate channel network that may favour enhanced cooling efficiency. The protruding pins 250b could furthermore extend along directions other than normal to the substrate plane such that air can still flow around their circumference.

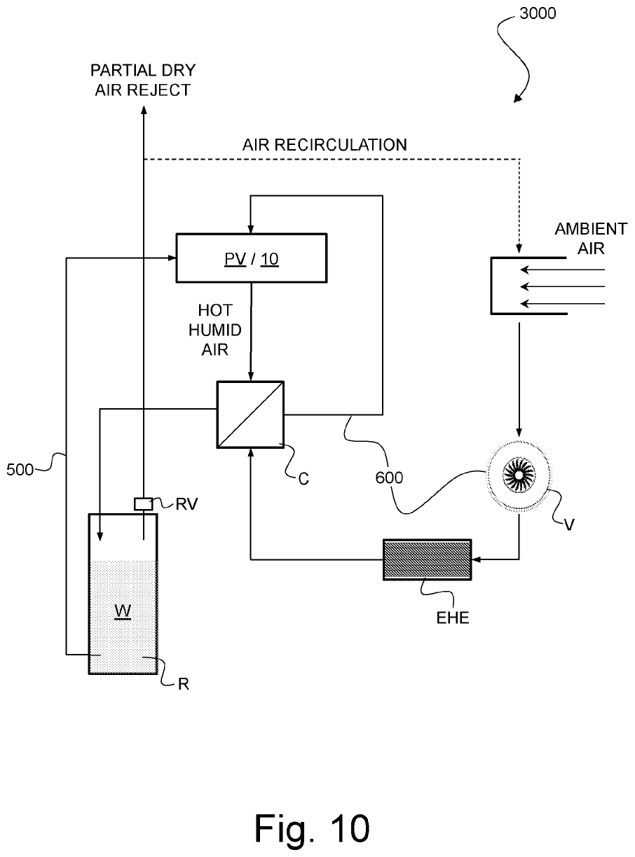

FIG. 10 is a schematic diagram of an embodiment of a solar energy harvesting system, namely a photovoltaic system 3000, having a photovoltaic device PV that is provided with a cooling apparatus 10 in accordance with the invention, which system 3000 further implements earth heat rejection and water recovery from the hot moist air exiting the cooling apparatus 10, as explained hereafter. The cooling apparatus 10 (which may be any cooling apparatus within the scope of the invention) is once again coupled to the relevant photovoltaic device PV to ensure appropriate cooling thereof.

As schematically shown in FIG. 10, hot moist air exiting the cooling apparatus 10 is channelled through a condenser C to undergo condensation, with a view to recover the condensed phase of the liquid cooling medium W. More specifically, the condenser C is flowed through by precooled ambient air that exits an earth heat exchanger EHE (such as underground pipes) that is fed with ambient air taken from the environment. Air exiting the condenser C is then led to the cooling apparatus 10 to sustain the evaporative cooling process as previously described. In the illustrated example, the relevant airflow circuitry 600 includes a ventilator V to cause forced ventilation of the ambient air through the system, including the earth heat exchanger EHE, condenser C, as well as the cooling apparatus 10.

The primary usage of the earth heat exchanger EHE is to maintain a stable ambient air inlet temperature to ensure stable condensation of hot moist air in the condenser C as well as a stable operation of the cooling apparatus 10 and associated photovoltaic device PV. Feeding ambient air at a stable temperature through the cooling apparatus 10 avoids significant junction temperature fluctuations in the associated photovoltaic device PV, which can otherwise result in a drop in photovoltaic efficiency and can negatively affect the durability of the photovoltaic device PV.

Condensate formed as a result of condensation of the hot humid air exiting the porous wick structure of the cooling apparatus 10 is recovered and collected in a reservoir R for re-wicking of the porous wick structure via the coolant circuitry 500. Reference sign RV in FIG. 10 designates a dehumidifying air vent (or membrane) for dry air rejection. Part of the dry air may be recirculated back to the airflow circuitry 600.

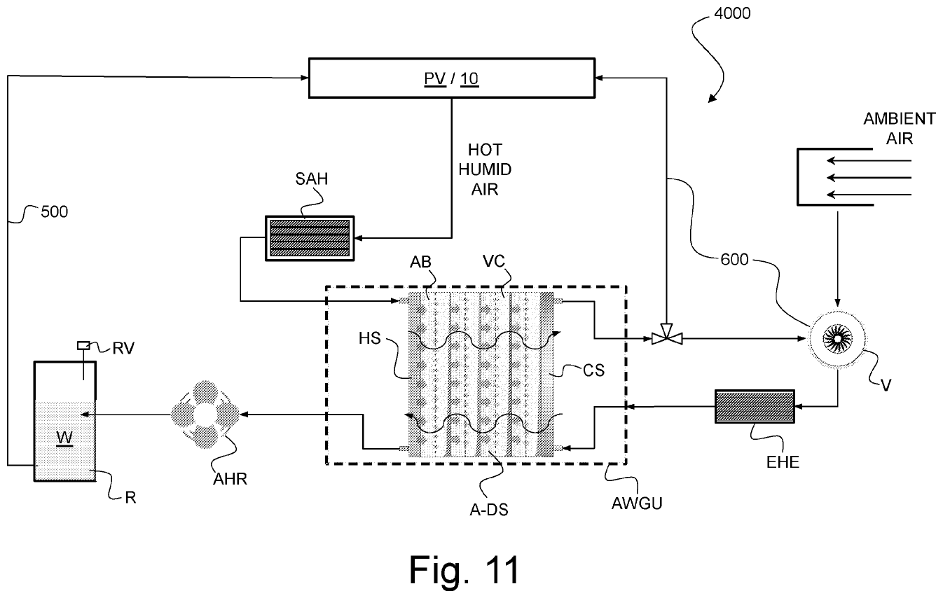

FIG. 11 is a schematic diagram of an embodiment of a combined solar energy harvesting and atmospheric water generation system, designated generally by reference numeral 4000, including a photovoltaic system having a photovoltaic device PV that is provided with a cooling apparatus 10 in accordance with the invention. The combined system 4000 also implements earth heat rejection and water recovery from the hot moist air exiting the cooling apparatus 10, albeit embodied in a different way. The cooling apparatus 10 (which may once again be any cooling apparatus within the scope of the invention) is similarly coupled to the relevant photovoltaic device PV to ensure appropriate cooling thereof.

Co-generating of electricity and water is of a particular interest in that the regions with the highest level on sun irradiation are also commonly suffer from water scarcity issues. The evaporative cooling principle of the invention requires e.g. water as liquid cooling medium, which can adequately be supplied by the atmospheric water generation system, namely by extracting the water required for cooling from the ambient air.

As schematically shown in FIG. 11, hot moist air exiting the cooling apparatus 10 is channelled through part of an adsorption-desorption system A-DS (namely a heat exchanger stage HS thereof) of an atmospheric water generation unit AWGU to likewise undergo condensation, with a view to recover part of the liquid cooling medium W. The adsorption-desorption system A-DS could be any suitable adsorption-desorption system as known for performing atmospheric water generation/harvesting (AWG/AWH). Preferably, the adsorption-desorption system A-DS is based on the adsorption-desorption principle disclosed in International (PCT) Application No. PCT/IB2021/059253 of Oct. 8, 2021, entitled “ATMOSPHERIC WATER GENERATION SYSTEM AND METHOD”, in the name of the present Applicant, the content of which is incorporated herein by reference in its entirety.

For the purpose of the present invention, it suffices to understand that the adsorption-desorption system A-DS depicted in FIG. 11 in essence comprises a plurality of processing stages (or “effects”) arranged in sequence, each including an adsorbent bed AB coupled to an adjacent vapor chamber VC via a vapor permeable separation wall (four such stages/effects being shown in FIG. 11). The adsorption-desorption system A-DS further includes a heat exchanger stage HS to provide thermal energy to the adsorbent beds AB and a condenser stage CS to cause condensation of water vapor in at least a final one of the vapor chambers VC. Each adsorbent bed AB contains an adsorbent material (such as packed silica gel or zeolites) to adsorb water contained in ambient air that is made to circulate through the adsorbent beds AB during an adsorption phase. During a subsequent desorption phase, thermal energy is provided by the heat exchanger stage HS to cause water adsorbed in the adsorbent beds AB to be desorbed into water vapor, which water vapor permeates through the vapor permeable separation wall into the adjacent vapor chamber where the water vapor condenses into a condensate/distillate.

In the illustrated example, hot moist air exiting the cooling apparatus 10 is channelled through the heat exchanger stage HS of the adsorption-desorption system A-DS of the atmospheric water generation unit AWGU where it undergoes condensation. Prior to being fed to the heat exchanger stage HS, temperature of the hot humid air is advantageously increased, in particular to a temperature of approximately 90° C. or more. This is ideally done by feeding the hot humid air exiting the porous wick structure of the cooling apparatus 10 through a solar air heater device SAH. Feeding of the heat exchanger stage HS of the adsorption-desorption system A-DS with the hot humid air exiting the cooling apparatus 10, further heated by the solar air heater device SAH, causes condensation in the heat exchanger stage HS, thereby releasing latent heat to sustain desorption in the adsorption-desorption system A-DS.

Condensate formed as a result of condensation in the heat exchanger stage HS may be recovered and collected in the reservoir R, much like in the case of the system 3000 depicted in FIG. 10, for re-wicking of the porous wick structure of the cooling apparatus 10. Prior to that, the condensate may be subjected to ambient heat rejection via a suitable ambient heat rejection device AHR.

Reference sign RV in FIG. 11 similarly designates a dehumidifying air vent (or membrane) provided on the reservoir R for dry air rejection.

In a manner similar to the system 3000 depicted in FIG. 10, the combined system 4000 of FIG. 11 further comprises an earth heat exchanger EHE to pre-cool ambient air prior to feeding it to the porous wick structure of the cooling apparatus 10. More specifically, in the illustrated example, the condenser stage CS of the adsorption-desorption system A-DS is flowed through by the pre-cooled ambient air exiting the earth heat exchanger EHE. Part of the pre-cooled ambient air exiting the condenser stage CS is fed to the porous wick structure of the cooling apparatus 10 to sustain evaporative cooling, while the remaining part thereof is cycled back into the system.

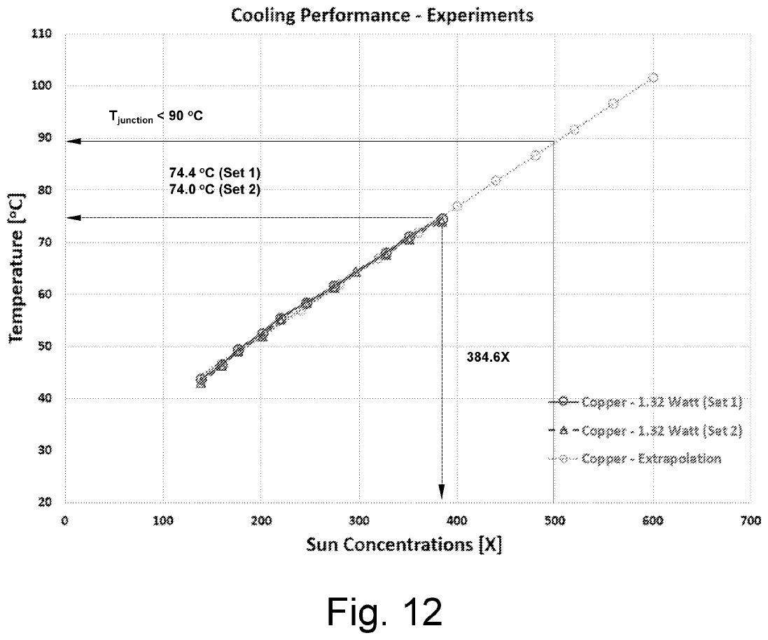

FIG. 12 is a chart showing experimental results obtained with a prototype of a cooling apparatus designed in accordance with the principle shown in FIG. 1. Experiments have been carried out on a substrate consisting of copper with six cavities having a width of 4.5 mm and a height of 9.6 mm, and a sintered wick structure having a nominal thickness of approximately 100 μm. Heater emulator area (A) was of 26 mm in width and 10 mm in length (i.e. an area of 260 mm²) with a maximum heater power (P) of 100 W. Total consumption of coolant (namely water) amounted to approximately 200 mL/h for an emulated sun concentration of 384.6× equivalent to 384.6 kW/m² (=P/A). Fan power consumption (electrical) was of 1.32 W, yielding an Energy Efficiency Ratio (EER), defined as the ratio of heater power over fan power consumption, of 75.75 (=100/1.32).

Two sets of overlapping experimental data are shown in the chart of FIG. 12. The experimental data clearly demonstrates repeatability of the evaporative cooling concept of the invention, with measured junction temperatures clearly overlapping each other and the temperature rising in a linear manner with rising sun concentration number. From the experimental results, a junction temperature of 70° C. was registered at a sun concentration of approximately 350X (i.e. 350 kW/m²), while a junction temperature of 74.0° C. to 74.4° C. was registered at a sun concentration of 384.6X (i.e. 384.6 kW/m²). By extrapolating further, a sun concentration of up to 500X (i.e. 500 kW/m²) would yield a junction temperature of approximately 90° C., which is an optimal temperature for operation of the atmospheric water generation unit AWGU of FIG. 11.

Various modifications and/or improvements may be made to the above-described embodiments without departing from the scope of the invention as defined by the appended claims.

In particular, as already mentioned, while the relevant evaporative cooling principle of the invention has been described in the particular context of an application thereof in the field of photovoltaics (PV), other applications could be contemplated, including e.g. thermal management of power electronics.

### LIST OF REFERENCE NUMERALS AND SIGNS USED THEREIN

10, 10.1-6 cooling apparatus/evaporative cooler
PV, PV_{A}, PV_{B} photovoltaic device/cell(s)
WS (sintered) porous wick structure
WS_{W} (sintered) porous wick structure (wetted)
100 thermally conductive substrate
100a cavities formed within thermally conductive substrate 100
100A passage for airflow and exposure of porous wick structure WS to air
105 thermally conductive substrate component attached to thermally conductive substrate 100
105a channels formed within thermally conductive substrate component 105
105A passage for airflow and exposure of porous wick structure WS to air
106A air inlet at inlet side of porous wick structure WS
106B air outlet at outlet side of porous wick structure WS
106W coolant inlet for wetting of porous wick structure WS
110 cooling manifold
110A air inlet port of cooling manifold 110/airflow inlet communicating with air inlet 106A
110B air outlet port of cooling manifold 110/airflow outlet communicating with air outlet 106B
110W coolant port of cooling manifold 110 for wetting of porous wick structure WS/supply port of liquid cooling medium W communicating with coolant inlet 106W
120 thermally conductive coating
200 (sintered) porous wick structure
200a longitudinal cavities formed through porous wick structure 200
200A passage for airflow through longitudinal cavities 200a/exposure of porous wick structure 200 to air
220 (sintered) porous wick structure/channelled fin structure
220a longitudinal channels formed on porous wick structure 220
220b longitudinal fins defining and separating longitudinal channels 220a
220A passage for airflow along longitudinal channels 220a/exposure of porous wick structure 220 to air
250 (sintered) porous wick structure/pin-fin structure
250a channel network formed on porous wick structure 250
250b protruding pins defining channel network 250a
250A passage for airflow along channel network 250a/exposure of porous wick structure 250 to air
500 coolant circuitry for wetting of porous wick structure WS
600 airflow circuitry for subjecting wetted porous wick structure WS to action of airflow and inducing cooling by evaporation
W liquid cooling medium (e.g. water) for wetting of porous wick structure WS
IN inlet side of porous wick structure WS/airflow inlet
OUT outlet side of porous wick structure WS/airflow outlet
100 solar energy harvesting system/concentrated photovoltaic (CPV) system
2000 solar energy harvesting system/concentrated photovoltaic (CPV) system
3000 solar energy harvesting system (photovoltaic system) with earth heat rejection and water recovery
4000 combined solar energy harvesting and atmospheric water generation system
SL sunlight
M concave mirror for concentration of sunlight SL onto photovoltaic device PV
FL converging Fresnel lens for concentration of sunlight SL onto photovoltaic device PV
C condenser
V ventilator
EHE earth heat exchanger (e.g. underground pipe(s))
SAH solar air heater device
AWGU atmospheric water generation unit
A-DS adsorption-desorption system of atmospheric water generation unit AWGU
HS heat exchanger stage of adsorption-desorption system A-DS
CS condenser stage of adsorption-desorption system A-DS
AB adsorbent beds
VC vapor chambers
AHR ambient heat rejection device
R reservoir for recovery and collection of water W
RV dehumidifying air vent (membrane)

1.-58. (canceled)

59. A method of cooling a device generating thermal energy comprising the following steps:
(a) providing a thermally conductive substrate coupled to a portion of the device generating thermal energy to allow heat transfer from the device generating thermal energy to the thermally conductive substrate;
(b) providing a porous wick structure coupled to the thermally conductive substrate, which porous wick structure is configured to be wettable by a liquid cooling medium and be partly exposed to air;
(c) wetting the porous wick structure by means of the liquid cooling medium; and
(d) subjecting the wetted porous wick structure to the action of an airflow to cause evaporation of the liquid cooling medium at an interface between the wetted porous wick structure and air, thereby inducing cooling by evaporation.

60. The method according to claim 59, wherein the porous wick structure is a sintered porous wick structure provided on the thermally conductive substrate.

61. The method according to claim 59, further comprising the step of providing a thermally conductive coating at an interface between the thermally conductive substrate and the porous wick structure.

62. The method according to claim 59, wherein the thermally conductive substrate includes a plurality of cavities or channels, the porous wick structure being provided on inner walls of the cavities or channels to leave a passage for the airflow, or
wherein the porous wick structure is configured to create a plurality of cavities or channels leaving a passage for the airflow.

63. The method according to claim 62, wherein the plurality of cavities or channels consists of a plurality of individual cavities or channels extending parallel to one another.

64. The method according to claim 59, wherein the porous wick structure is configured to create a plurality of channels leaving a passage for the airflow, and
wherein the porous wick structure includes a plurality of protruding pins that are spaced apart to create the passage for the airflow between and around a circumference of the protruding pins.

65. The method according to claim 64, wherein the protruding pins are distributed to form an array of protruding pins that extend substantially perpendicularly to the path of the airflow.

66. The method according to claim 65, wherein the protruding pins are arranged in a regular pattern of rows and columns.

67. The method according to claim 65, wherein the protruding pins are arranged in a staggered pattern.

68. The method according to claim 59, wherein wetting of the porous wick structure at step (c) is performed by capillary action.

69. The method according to claim 59, wherein the liquid cooling medium is supplied to the porous wick structure by means of a pump.

70. The method according to claim 59, wherein the liquid cooling medium includes water.

71. The method according to claim 59, wherein subjecting of the wetted porous wick structure to the action of the airflow at step (d) is performed by forced ventilation of ambient air.

72. The method according to claim 71, wherein ambient air is pre-cooled via an earth heat exchanger prior to feeding it to the porous wick structure.

73. The method according to claim 59, wherein the porous wick structure has a porosity of approximately 20% to 80%.

74. The method according to claim 59, wherein the porous wick structure exhibits pores having an average size comprised between approximately 5 μm and 50 μm.

75. The method according to claim 59, wherein the porous wick structure exhibits a thickness comprised between approximately 0.1 mm and 3 mm.

76. The method according to claim 59, wherein the thermally conductive substrate is a metallic substrate or a silicon substrate.

77. The method according to claim 76, wherein the metallic substrate is an aluminium, copper or steel substrate.

78. The method according to claim 59, wherein hot humid air exiting the porous wick structure is channelled through a condenser to undergo condensation.

79. The method according to claim 59, wherein hot humid air exiting the porous wick structure is channelled through a heat exchanger stage of an adsorption-desorption system of an atmospheric water generation unit where the hot humid air undergoes condensation, thereby releasing latent heat to sustain desorption in the adsorption-desorption system.

80. The method according to claim 79, further comprising the step of increasing the temperature of the hot humid air exiting the porous wick structure prior to feeding it to the heat exchanger stage of the adsorption-desorption system.

81. The method according to claim 80, wherein the temperature of the hot humid air exiting the porous wick structure is increased by means of a solar air heater device.

82. The method according to claim 80, wherein the hot humid air is increased up to a temperature of approximately 90° C. or more.

83. The method according to claim 79, wherein condensate formed as a result of condensation in the heat exchanger stage of the adsorption-desorption system is subjected to ambient heat rejection.

84. The method according to claim 78, wherein condensate formed as a result of condensation of the hot humid air exiting the porous wick structure is recovered and collected in a reservoir for re-wicking of the porous wick structure.

85. The method according to claim 59, wherein the device generating thermal energy is a photovoltaic device comprising one or more photovoltaic cells.

86. The method according to claim 85, wherein the photovoltaic device is a concentrated photovoltaic device.

87. A cooling apparatus for carrying out cooling of a device generating thermal energy, comprising:
a thermally conductive substrate that can be coupled to a portion of the device generating thermal energy to allow heat transfer from the device generating thermal energy to the thermally conductive substrate;
a porous wick structure coupled to the thermally conductive substrate, which porous wick structure is configured to be wettable by a liquid cooling medium and to be exposed to air;
coolant circuitry configured to wet the porous wick structure by means of the liquid cooling medium, which coolant circuitry is coupled to the porous wick structure to supply the liquid cooling medium; and
airflow circuitry configured to subject the wetted porous wick structure to the action of an airflow to cause evaporation of the liquid cooling medium at an interface between the wetted porous wick structure and air, thereby inducing cooling by evaporation.

88. The cooling apparatus according to claim 87, wherein the porous wick structure is a sintered porous wick structure provided on the thermally conductive substrate.

89. The cooling apparatus according to claim 87, further comprising a thermally conductive coating provided at an interface between the thermally conductive substrate and the porous wick structure.

90. The cooling apparatus according to claim 87, wherein the thermally conductive substrate includes a plurality of cavities or channels, the porous wick structure being formed on inner walls of the cavities or channels to leave a passage for the airflow, or
wherein the porous wick structure is configured to create a plurality of cavities or channels leaving a passage for the airflow.

91. The cooling apparatus according to claim 90, wherein the plurality of cavities or channels consists of a plurality of individual cavities or channels extending parallel to one another.

92. The cooling apparatus according to claim 87, wherein the porous wick structure is configured to create a plurality of channels leaving a passage for the airflow,
and wherein the porous wick structure includes a plurality of protruding pins that are spaced apart to create the passage for the airflow between and around a circumference of the protruding pins.

93. The cooling apparatus according to claim 92, wherein the protruding pins are distributed to form an array of protruding pins that extend substantially perpendicularly to the path of the airflow.

94. The cooling apparatus according to claim 93, wherein the protruding pins are arranged in a regular pattern of rows and columns.

95. The cooling apparatus according to claim 93, wherein the protruding pins are arranged in a staggered pattern.

96. The cooling apparatus according to claim 87, wherein the coolant circuitry is configured to wet the porous wick structure by capillary action.

97. The cooling apparatus according to claim 87, wherein the coolant circuitry includes a pump to supply the liquid cooling medium to a coolant inlet of the porous wick structure.

98. The cooling apparatus according to claim 87, wherein the liquid cooling medium includes water.

99. The cooling apparatus according to claim 87, wherein the airflow circuitry includes a ventilator to cause forced ventilation of ambient air.

100. The cooling apparatus according to claim 87, further comprising a cooling manifold including a coolant port coupled to a coolant inlet for wetting of the porous wick structure by means of the liquid cooling medium, an air inlet port coupled to an air inlet at an inlet side of the porous wick structure, and an air outlet port coupled to an air outlet at an outlet side of the porous wick structure.

101. The cooling apparatus according to claim 87, wherein the porous wick structure has a porosity of approximately 20% to 80%.

102. The cooling apparatus according to claim 87, wherein the porous wick structure exhibits pores having an average size comprised between approximately 5 μm and 50 μm.

103. The cooling apparatus according to claim 87, wherein the porous wick structure exhibits a thickness comprised between approximately 0.1 mm and 3 mm.

104. The cooling apparatus according to claim 87, wherein the thermally conductive substrate is a metallic substrate or a silicon substrate.

105. The cooling apparatus according to claim 104, wherein the metallic substrate is as an aluminium, copper or steel substrate.

106. A solar energy harvesting system comprising a solar energy harvesting device that is thermally coupled to a cooling apparatus according to claim 87.

107. The solar energy harvesting system according to claim 106, wherein the solar energy harvesting device includes one or more photovoltaic cells thermally coupled to the cooling apparatus.

108. The solar energy harvesting system according to claim 107, further comprising a sunlight concentrating structure configured to concentrate sunlight onto the one or more photovoltaic cells.

109. The solar energy harvesting system according to claim 106, further comprising an earth heat exchanger to pre-cool ambient air prior to feeding it to the porous wick structure.

110. The solar energy harvesting system according to claim 106, further comprising a condenser configured to subject the hot humid air exiting the porous wick structure to condensation.

111. The system according to claim 110, further comprising a reservoir to recover and collect condensate formed as a result of condensation of the hot humid air exiting the porous wick structure for re-wicking of the porous wick structure.

112. A combined solar energy harvesting and atmospheric water generation system comprising:
at least one atmospheric water generation unit including an adsorption-desorption system configured to extract water from ambient air; and
a solar energy harvesting system in accordance with claim 106,
wherein the adsorption-desorption system comprises a heat exchanger stage which is flowed through by hot humid air exiting the porous wick structure to undergo condensation, thereby releasing latent heat to sustain desorption in the adsorption-desorption system.

113. The system according to claim 112, further comprising an earth heat exchanger to pre-cool ambient air prior to feeding it to the porous wick structure,
wherein the adsorption-desorption system further comprises a condenser stage which is flowed through by pre-cooled ambient air exiting the earth heat exchanger,
and wherein part of the pre-cooled ambient air exiting the condenser stage of the adsorption-desorption system is fed to the porous wick structure.

114. The system according to claim 112, further comprising a solar air heater device to increase the temperature of the hot humid air exiting the porous wick structure prior to feeding it to the heat exchanger stage of the adsorption-desorption system.

115. The system according to claim 114, wherein the solar air heater device is configured to increase the temperature of the hot humid air up to approximately 90° C. or more.

116. The system according to claim 112, further comprising an ambient heat rejection device to subject condensate exiting the heat exchanger stage of the adsorption-desorption system to ambient heat rejection.
